(19) United States
(12) Patent Application Publication
(10) Pub. No.: US 2014/0184265 A1
(43) Pub. Date: Jul. 3, 2014

(54) TEST CIRCUIT FOR POWER SUPPLY UNIT

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventor: HAI-QING ZHOU, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 14/142,913

(22) Filed: Dec. 29, 2013

(30) Foreign Application Priority Data
Dec. 29, 2012 (CN) 2012105894393

(51) Int. Cl. G01R 31/40

(52) U.S. Cl. CPC G01R 31/40
USPC 324/764.01

(57) ABSTRACT

A test circuit includes a power supply unit, a number of resistors, a switch, and a number of light-emitting diodes (LEDs). A first pin of the power supply unit is coupled to the switch. A second pin of the power supply unit is coupled to a system power terminal The first system power terminal is coupled to an anode of a first LED through a first resistor. A cathode of the first LED is grounded. When the switch is turned on, the power supply unit receives a power-on signal through the first pin. If the power supply unit is qualified, the first LED emits light.

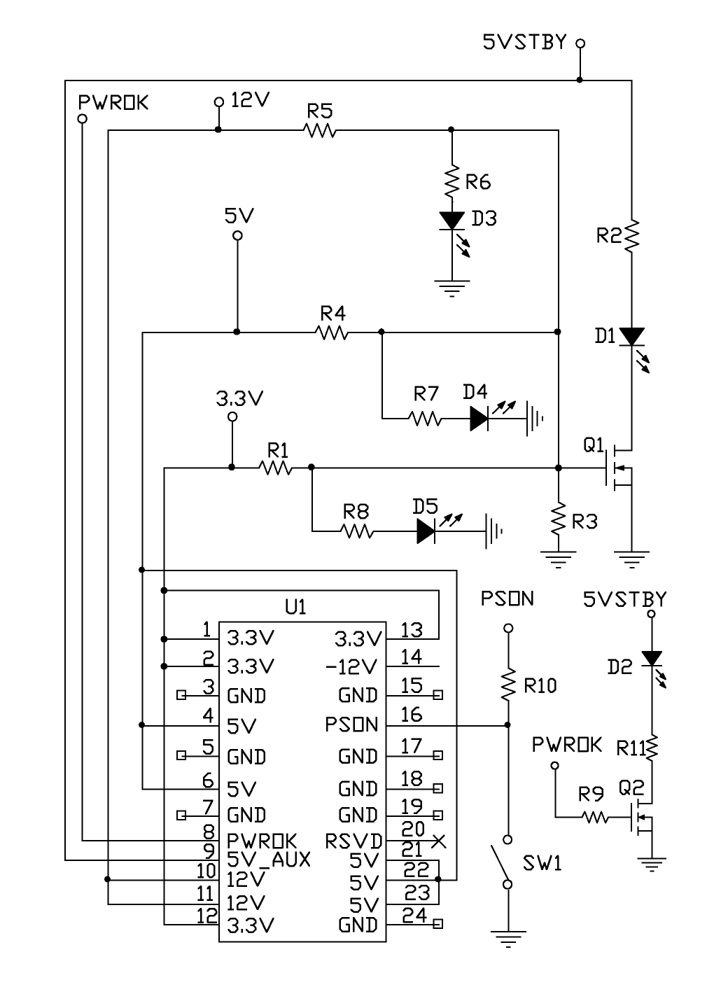

### BACKGROUND

1. Technical Field

The present disclosure relates to test circuits, and particularly to a test circuit for a power supply unit.

2. Description of Related Art

In order to determine whether a power supply unit is qualified, the power supply unit is tested using an oscillograph. Because the power supply unit may output different voltages, such as 5 volts (V), 12V, and 3.3V, as well as a power good signal (PWR OK), it is inconvenient to test all voltages and the power good signal of the power supply unit one-by-one with the oscillograph.

Therefore, there is need for improvement in the art.

### BRIEF DESCRIPTION OF THE DRAWING

Many aspects of the present disclosure can be better understood with reference to the following drawing(s). The components in the drawing(s) are not necessarily drawn to scale, the emphasis instead being placed upon clearly illustrating the principles of the present disclosure. Moreover, in the drawing(s), like reference numerals designate corresponding parts throughout the several views.

The FIGURE is a circuit diagram of an embodiment of a test circuit for a power supply unit.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

The figure illustrates an embodiment of a test circuit. The test circuit comprises a power supply unit U1, eleven resistors RI-RH, two metal-oxide semiconductor field-effect transistors (MOSFETs) Q1 and Q2, and five light-emitting diodes (LEDs) D1-D5.

The power supply unit U1 comprises a first to twenty-fourth pin 1-24. The first, second, and twelfth pins 1, 2, 12 of the power supply unit U1 are coupled to a system power terminal 3.3V. The fourth, sixth, and twenty-first through twenty-third pins 4, 6, 21-23 of the power supply unit U1 are coupled to a system power terminal 5V. The eighth pin 8 of the power supply unit U1 outputs a power good signal (PWROK). The ninth pin 9 of the power supply unit U1 is coupled to a standby power terminal 5VSTBY. The tenth and eleventh pins 10 and 11 of the power supply unit U1 are coupled to a system power terminal 12V. The sixteenth pin 16 of the power supply unit U1 is electrically connected to a motherboard to receive a power-on signal (PSON) through the resistor R10, and is grounded through a switch SW1. The fourteenth pin 14 of the power supply unit U1 is coupled to a system power terminal −12V. The other pins of the power supply unit U1 are grounded.

The system power terminal 3.3V is electrically connected to an anode of the LED D5 through the resistors R1 and R8 in that order. A cathode of the LED D5 is grounded. A node between the resistors R1 and R8 is coupled to a gate of the MOSFET Q1. The gate of the MOSFET Q1 is grounded through the resistor R3. A source of the MOSFET Q1 is grounded.

The system power terminal 5V is electrically connected to an anode of the LED D4 through the resistors R4 and R7 in that order. A cathode of the LED D4 is grounded. A node between the resistors R4 and R7 is coupled to the gate of the MOSFET Q1.

The system power terminal 12V is electrically connected to an anode of the LED D3 through the resistors R5 and R6 in that order. A cathode of the LED D3 is grounded. A node between the resistors R5 and R6 is coupled to the gate of the MOSFET Q1.

The standby power terminal 5 VSTBY is electrically connected to an anode of the LED D1 through the resistor R2. A cathode of the LED D1 is electrically connected to a drain of the MOSFET Q1.

A gate of the MOSFET Q2 is coupled to the eighth pin 8 of the power supply unit U1 through the resistor R9. A source of the MOSFET Q2 is grounded, and a drain of the MOSFET Q2 is coupled to a cathode of the LED D2. An anode of the LED D2 is coupled to the standby power terminal 5VSTBY.

When the power supply unit U1 receives a low-voltage level power-on signal, such as logic 0, through the sixteenth pin 16, the power supply unit U1 outputs all voltages of the test circuit after a certain time duration. After all the voltages of the test circuit are output, a high-voltage level power good signal, such as logic 1, is outputted by the power supply unit U1 through the eighth pin 8.

When the switch SW1 is turned on to simulate the power-on signal generated by the motherboard, the system power terminals 12V, 5V, and 3.3V all output corresponding voltages, the LEDs D3, D4, and D5 emit light, and the gate of the MOSFET Q1 is at a high-voltage level by setting suitable resistances of the corresponding resistors R1, R8, R4, R7, R5, and R3. Thus, the MOSFET Q1 is turned on, and the LED D1 emits light. Accordingly, the LEDs D3, D4, and D5 can be used to determine whether the system power terminals 12V, 15V, and 3.3V operate normally. If one or more of the system power terminals 12V, 5V, and 3.3V do not output the corresponding voltage, the corresponding LEDs do not emit light. For example, if the system power terminal 12V does not output the corresponding voltage, the LED D3 does not emit light, so the gate of the MOSFET Q1 is at a low-voltage level, and the MOSFET Q1 is turned off. Thus, the LED D1 does not emit light.

If all the system power terminals output the corresponding voltages, the power supply unit U1 outputs a high-voltage level power good signal through the eighth pin 8. Accordingly, the gate of the MOSFET Q2 is at a high-voltage level, and the MOSFET Q2 is turned on. Therefore, the LED D2 emits light.

In the embodiment, the MOSFETs Q1 and Q2 are n-channel MOSFETs. In other embodiments, the MOSFETs Q1 and Q2 can be replaced by other electronic switches, such as bipolar junction transistors.

While the disclosure has been described by way of example and in terms of a preferred embodiment, it is to be understood that the disclosure is not limited thereto. On the contrary, it is intended to cover various modifications and similar arrangements as would be apparent to those skilled in the art. Therefore, the range of the appended claims should be accorded the broadest interpretation so as to encompass all such modifications and similar arrangements.

What is claimed is:

1. A test circuit comprising:
a switch;
a first resistor;
a first light-emitting diode (LED); and
a power supply unit comprising a first pin and a second pin, wherein the first pin is coupled to the switch, the second pin is coupled to a first system power terminal, the first system power terminal is coupled to an anode of the first LED through the first resistor, and a cathode of the first LED is connected to ground; when the switch is turned on, the power supply unit receives a power on signal through the first pin; when the power supply unit outputs a first system voltage to the first LED through the first system power terminal, the first LED emits light.

2. The test circuit of claim 1, further comprising a second resistor and a second LED, wherein a third pin of the power supply unit is coupled to a second system power terminal, the second system power terminal is coupled to an anode of the second LED through the second resistor, and a cathode of the second LED is connected to ground; when the power supply unit outputs a second system voltage to the second LED through the second system power terminal, the second LED emits light.

3. The test circuit of claim 2, further comprising a third resistor and a third LED, wherein a fourth pin of the power supply unit is coupled to a third system power terminal, the third system power terminal is coupled to an anode of the third LED through the third resistor, and a cathode of the third LED is connected to ground; when the power supply unit outputs a third system voltage to the third LED through the third system power terminal, the third LED emits light.

4. The test circuit of claim 3, further comprising a fourth resistor, a fifth resistor, a fourth LED, and a first electronic switch comprising a first terminal, a second terminal, and a third terminal, wherein a fifth pin of the power supply unit is coupled to a fourth power terminal, to output a standby voltage, the first terminal of the first electronic switch is connected to ground through the fourth resistor, and is coupled to the anodes of the first, second, and third LEDs, the second terminal of the first electronic switch is connected to ground, the third terminal of the first electronic switch is coupled to a cathode of the fourth LED, and an anode of the fourth LED is coupled to the fifth pin of the power supply unit; when the first terminal of the first electronic switch is at a high-voltage level, the second terminal of the first electronic switch is connected to the third terminal of the first electronic switch; when the first terminal of the first electronic switch is at a low-voltage level, the second terminal of the first electronic switch is disconnected from the third terminal of the first electronic switch; when the power supply unit outputs the first, second, and third system voltages, the first electronic switch is turned on, the fourth LED emits light.

5. The test circuit of claim 4, further comprising a second electronic switch comprising a first terminal, a second terminal, and a third terminal, a sixth resistor, and a fifth LED, wherein a sixth pin of the power supply unit is coupled to the first terminal of the second electronic switch to receive a power good signal from the power supply unit, the second terminal of the second electronic switch is connected to ground, the third terminal of the second electronic switch is coupled to a cathode of the fifth LED, and an anode of the fifth LED is coupled to the standby power terminal; when the first terminal of the second electronic switch is at a high-voltage level, the second terminal of the second electronic switch is connected to the third terminal of the second electronic switch; when the first terminal of the second electronic switch is at a low-voltage level, the second terminal of the second electronic switch is disconnected from the third terminal of the second electronic switch; when the power supply unit outputs the power good signal, the fifth LED emits light.

6. The test circuit of claim 5, further comprising a seventh resistor, wherein the first pin of the power supply unit receives the power on signal through the seventh resistor.

7. The test circuit of claim 6, further comprising an eighth resistor, a ninth resistor, and a tenth resistor, wherein the anode of the first LED is coupled to the first resistor through the eighth resistor, the first terminal of the first electronic switch is coupled to a node between the first and eighth resistors; the anode of the second LED is coupled to the second resistor through the ninth resistor, the first terminal of the first electronic switch is coupled to a node between the second and ninth resistors; the anode of the third LED is coupled to the third resistor through the tenth resistor, and the first terminal of the first electronic switch is coupled to a node between the third and ninth resistors.

8. The test circuit of claim 7, wherein the first and second electronic switches are n-channel metal oxide semiconductor field effect transistors (nMOSFETs), and the first terminals, the second terminals, and the third terminals of the first and second electronic switches are gates, sources, and drains of the nMOSFETs.
